(19) United States
(12) Patent Application Publication
(10) Pub. No.: US 2016/0025963 A1
(43) Pub. Date: Jan. 28, 2016

(54) DISPLAY DEVICE AND METHOD FOR PRODUCING SAME

(71) Applicant: PIXTRONIX, INC., San Diego, CA (US)

(72) Inventors: Naohisa Andou, Mobara City (JP); Hiroshi Kawanakago, Mobara City (JP); Kohei Takahashi, Mobara City (JP)

(21) Appl. No.: 14/774,046

(22) PCT Filed: Mar. 13, 2014
(86) PCT No.: PCT/US2014/026678

§ 371 Date: Sep. 9, 2015

(30) Foreign Application Priority Data
Mar. 14, 2013 (JP) 2013-051967

(51) Int. Cl. G02B 26/02; B81B 3/00; G02B 26/08

(52) U.S. Cl. CPC G02B 26/02; G02B 26/08; B81B 3/0008

(57) ABSTRACT

The objective is to cause a substrate on which a shutter is provided and a substrate that opposes it to be electrically continuous. [Means of Solution] On a first substrate 10, a shutter 28 that controls the passing or blocking of light, a driver 52 for driving the shutter 28, and a protruding part 62 having a plurality of side faces 66 rising from the first substrate 10 so as to circumscribe a prescribed space are respectively provided so as to contain a laminate structure of a first conducting film 54 and an insulating film 16. The outermost layer of the respective plurality of side faces 66 is made of the insulating film 16 that covers the first conducting film 54, and has an aperture 68 which exposes part of the first conducting film 54. Conducting particles 70 are arranged in the prescribed space circumscribed by the plurality of side faces 66, and on the side nearest the first substrate 10, contact the first conducting film 54 exposed from the aperture 68 in the plurality of side faces 66, and on the side nearest the second substrate 12, contact a second conducting film 22.

### RELATED APPLICATIONS

The present application for Patent claims priority to Japanese Application No. 2013-051967, entitled “Electrical Conduction Using Bead on Surface of Resist Sidewall,” filed Mar. 14, 2013, and assigned to the assignee hereof and hereby expressly incorporated by reference herein.

1. Technical Field

The present invention relates to a display device and a method for producing the same.

2. Background Art

A microelectromechanical system (MEMS) display is a display expected to supplant liquid crystal displays (refer to Patent Reference 1). This display opens and closes a transparent window using a mechanical shutter, unlike the liquid crystal shutter style which employs polarized light. More particularly, a shutter is provided for each pixel on a TFT substrate on which TFTs (thin film transistors) are formed, and an image is displayed by opening and closing the apertures by operating the shutters in the horizontal direction by electrostatic force.

### PRIOR ART REFERENCES

### Patent References

[Patent Reference 1] Japanese Unexamined Patent Application Publication No. 2008-197668

[Patent Reference 2] Japanese Unexamined Patent Application Publication No. 2001-215524

### SUMMARY OF THE INVENTION

### Problems the Invention is to Solve

Normally, to prevent the shutters from sticking to the opposing substrate, the shutters and the opposing substrate must be at the same electric potential. To do so, the opposing substrate and TFT substrate are caused to be electrically connected using a conductive material. The surface of the TFT substrate on which the shutters are provided is covered with a passivation film. Because the passivation film is formed from a hard material such as SiN, the passivation film cannot be pierced even using a method by pressing conductive particles as disclosed in Patent Reference 2, and it is difficult to make the opposing substrate and the TFT substrate electrically continuous.

The objective of the present invention is to cause a substrate on which shutters are provided and a substrate that opposes it to be electrically connected.

### Means for Solving Problems

(1) The display device pertaining to the present invention is includes a first substrate, a second substrate arranged so as to oppose the first substrate, a first conducting film provided on the side of the first substrate nearest the second substrate, an insulating film provided on the side of the first substrate nearest the second substrate so as to cover the first conducting film, a second conducting film provided on the side of the second substrate nearest the first substrate, and conducting particles interposed between the first substrate and second substrate, wherein, on the first substrate, a shutter which controls the passing or blocking of light, a driver for driving the shutter, and a protruding part having a plurality of side faces rising from the first substrate so as to circumscribe a prescribed space are respectively provided so as to contain a laminate structure of the first conducting film and the insulating film, and the outermost layer of the respective plurality of side faces is made of the insulating film that covers the first conducting film, and has an aperture which exposes part of the first conducting film, and the conducting particles are arranged in the prescribed space circumscribed by the plurality of side faces, and on the side nearest the first substrate, they contact the first conducting film exposed from the aperture in the plurality of side faces, and on the side nearest the second substrate, they contact the second conducting film. According to the present invention, the first conducting film formed on the first substrate on which shutters are provided and the second conducting film formed on the second substrate opposing can be made electrically connected. As a result, the shutters and substrates can be prevented from sticking together due to electrostatic force because the shutter and second substrate are at the same potential. The first conducting film which the conducting particles touch is part of the laminate structure which constitutes the protruding part that rises from the first substrate. On the side faces of the protruding part, the lamination direction of the insulating film and first conducting film is a direction that intersects the direction of opposition of the first substrate and second substrate. Therefore, when the first substrate is made to oppose the second substrate, due to the conducting particles moving in the direction in which the two oppose each other, an aperture is easily formed by the conducting particles peeling away part of the insulating film. Thus, the conducting particles and the first conducting film can connect electrically via the aperture in the insulating film.

(2) It may also be characterized in that, in the display device according to item (1), the insulating film further contains a portion which extends parallel to the surface of the first substrate, and the portion that constitutes the outermost layer of the plurality of side faces is thinner than the portion that extends parallel to the surface of the first substrate.

(3) It may also be characterized in that, in the display device according to item (1) or (2), the protruding part is provided continuously so as to enclose the prescribed space, and the plurality of side faces are formed integrally and continuously.

(4) It may also be characterized in that, in the display device according to item (1) or (2), the protruding part is formed in a fragmented manner so as to contain at least two opposing portions with a gap in between adjacent parts at positions that enclose the prescribed space, and the plurality of side faces are each side faces of at least two opposing portions.

(5) It may also be characterized in that, in the display device according to item (4), the at least two opposing portions are each formed in a stair-like pattern, and have a base and walls that rise from the base, and the plurality of side faces are side faces of the walls of the at least two opposing portions.

(6) It may also be characterized in that, in the display device according to item (4) or (5), the plurality of side faces each are a cylindrical face formed around an axis perpendicular to the first substrate.

(7) It may also be characterized in that, in the display device according to item (4) or (5), the plurality of side faces each have an exterior corner shape.

(8) It may also be characterized in that, in the display device according to item (4) or (5), the plurality of side faces each have an interior corner shape.

(9) It may also be characterized in that, in the display device according to any one of items (1) through (8), the conducting particles are elastically deformed by being pressed by the plurality of side faces.

(10) The method for producing a display device pertaining to the present invention includes providing, on the first substrate, a shutter which controls the passing or blocking of light, a driver for driving the shutter, and a protruding part having a plurality of side faces rising from the first substrate so as to circumscribe a prescribed space so as to contain a laminate structure of the first conducting film and the insulating film, providing a second conducting film on a second substrate, and making the side of the first substrate on which the first conducting film and insulating film are provided and the side of the second substrate on which the second conducting film is provided to oppose each other and interposing conducting particles between the first substrate and second substrate, wherein the outermost layer of each of the plurality of side faces is made of the insulating film that covers the first conducting film, the prescribed space circumscribed by the plurality of side faces is smaller than the conducting particles, and interposing the conducting particles by pressing the conducting particles in the prescribed region circumscribed by the plurality of side faces, the insulating film is chipped away and an aperture which exposes part of the first conducting film is formed in the insulating film, and the conducting particles, on the side nearest the first substrate, are put in contact with the first conducting film exposed from the aperture in the plurality of side faces, and on the side nearest the second substrate, are put in contact with the second conducting film.

### BRIEF DESCRIPTION OF THE DRAWINGS

FIG. 1 is a plan view schematically illustrating a display device pertaining of an embodiment of the present invention.

FIG. 2 is a cross-sectional view schematically illustrating a display device pertaining of the embodiment of the present invention.

FIG. 3 is an oblique view illustrating a shutter and a driver thereof.

FIG. 4 is a cross-sectional view illustrating details of the display device pertaining to the embodiment of the present invention.

FIG. 5 is a plan view of a protruding part.

FIG. 6 is a plan view illustrating modification example 1 of the protruding part.

FIG. 7 is a plan view illustrating modification example 2 of the protruding part.

FIG. 8 is a plan view illustrating modification example 3 of the protruding part.

FIG. 9 is a plan view illustrating modification example 4 of the protruding part.

FIG. 10 is a plan view illustrating modification example 5 of the protruding part.

### EMBODIMENTS

An embodiment of the present invention will be described below in reference to the drawings.

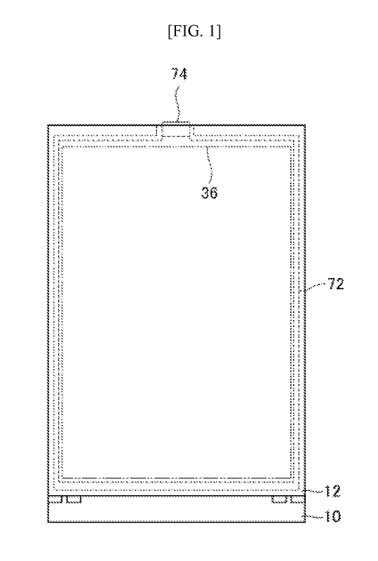

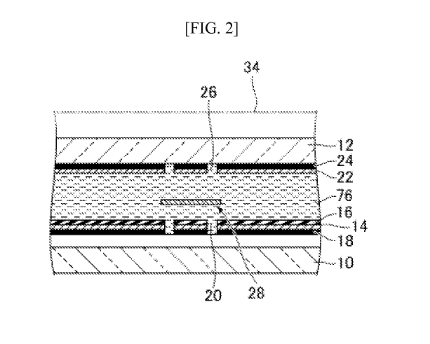

FIG. 1 is a plan view schematically illustrating a display device pertaining of an embodiment of the present invention. FIG. 2 is a cross-sectional view schematically illustrating a display device pertaining of the embodiment of the present invention.

The display device has a first substrate 10 and a second substrate 12, each made of transparent material such as glass. The first substrate 10 is a circuit board or thin film transistor (TFT) board on which thin film transistors, wires, etc. (not illustrated) are formed. On the side of the first substrate 10 nearest the second substrate 12, a conducting layer 14 made of, for example, ITO (indium tin oxide) is provided. On the side of the first substrate 10 nearest the second substrate 12, an insulating film 16 made of, for example, silicon nitride is provided so as to cover the conducting layer 14. The insulating film 16 includes a portion that extends parallel to the first substrate 10. A first opaque film 18 is formed on the first substrate 10. A first fixed aperture 20 is formed in the first opaque film 18.

The second substrate 12 is arranged so as to oppose the first substrate 10 with a gap in between. On the side of the second substrate 12 nearest the first substrate 10, a second conducting film 22 made of, for example, ITO is provided. A second opaque film 24 is formed on the second substrate 12. A second fixed aperture 26 is formed in the second opaque film 24. The first fixed aperture 20 and second fixed aperture 26 are formed so as to oppose each other.

A plurality of shutters 28 are provided on the first substrate 10. The shutters 28 control the passing or blocking of light. The shutters 28 are provided above a set of TFTs, wires, etc. (not illustrated) such that they can move.

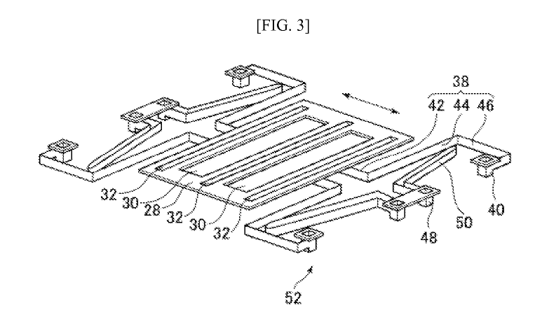

FIG. 3 is an oblique view illustrating a shutter and a driver thereof The shutter 28 is a plate having a drive aperture 30. To increase strength, depressions 32 are formed in the shutter 28, but the depressions 32 do not penetrate through. Light passes through the drive aperture 30, and is blocked in portions other than the drive aperture 30. The drive aperture 30 has a shape that is long in one direction. Furthermore, light is supplied from a backlight 34 (refer to FIG. 2) stacked on the first substrate 10 or second substrate 12.

The drive aperture 30 of the shutter 28 and first fixed aperture 20 of the first opaque film 18 and the second fixed aperture 26 of the second opaque film 24 are arranged in opposing positions. If they are aligned, light passes through, and if the first fixed aperture 20 and second fixed aperture 26 are blocked due to movement of the shutter 28, light is blocked. In other words, the shutter 28 is mechanically driven so as to control passing and blocking of light to the first fixed aperture 20 and second fixed aperture 26. One shutter corresponds to one pixel, and an image is displayed by a plurality of pixels. For this reason, a plurality of shutters 28 are provided. The shutters 28 are arranged in an image display region 36 (refer to FIG. 1) which displays an image according to the presence or absence and the output duration of light passing through the drive aperture 30 and the first aperture 20 and second aperture 26.

The shutter 28 is supported on a first spring 38 so as to be suspended above the first substrate 10. The shutter 28 is supported by a plurality of first springs 38. The first spring 38 is affixed to the first substrate 10 by a first anchor 40.

The first spring 38 is made of an elastically deformable material. The first spring 38 has a thin sheet shape, where the direction of thickness is arranged in the horizontal direction (direction parallel to the sheet face of the first substrate 10), and the direction of width is arranged in the vertical direction (direction perpendicular to the sheet face of the first substrate 10). As a result, the first spring 38 can deform in the horizontal direction, which is its direction of thickness.

The first spring 38 has a first part 42 which extends in a direction away from the shutter 28 (a direction which intersects (e.g., is perpendicular to) the long direction of the drive aperture 30), a second part 44 which extends outward from the center in the long direction of the drive aperture 30, which is the direction along the long direction of the drive aperture 30, and a third part 46 which extends in a direction away from the shutter 28 (a direction which intersects (e.g., is perpendicular to) the long direction of the drive aperture 30). Also, the shutter 28 is supported on the first spring 38 such that it can move in a direction that intersects (e.g., is perpendicular to) the long direction of the drive aperture, as indicated by the arrows in FIG. 3.

On the first substrate 10, a second spring 50 supported by a second anchor 48 is provided. The second spring 50 is also made of an elastically deformable material. The second spring 50 has a thin sheet shape, where the direction of thickness is arranged in the horizontal direction (direction parallel to the sheet face of the first substrate 10), and the direction of width is arranged in the vertical direction (direction perpendicular to the sheet face of the first substrate 10). As a result, the second spring 50 can deform in the horizontal direction, which is its direction of thickness. Further, the second spring 50 has a loop shape, where a band-like part which extends from the second anchor 48 is bent and folded so as to return to the same second anchor 48.

The second spring 50 opposes the second part 44 of the first spring 38 on the side further from the shutter 28 than the second part 44. The second part 44 of the first spring 38 is attracted to the second spring 50 by electrostatic force produced by the potential difference between the second part 44 of the first spring 38 and the second spring 50 produced by applying voltage to the second anchor 48. When the second part 44 is attracted, the shutter 28 is also attracted via the first part 42 which is integrated with the second part 44. In short, the first spring 38 and second spring 50 constitute a drive unit 52 for mechanically driving the shutter 28.

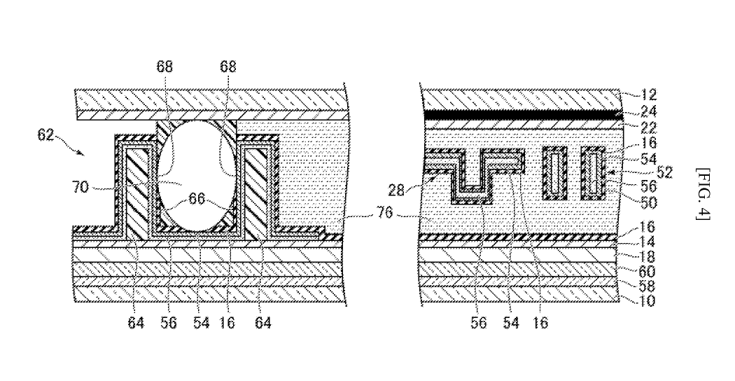

FIG. 4 is a cross-sectional view illustrating details of the display device pertaining to one embodiment of the present invention. The shutter 28 contains a laminate structure of the first conducting film 54 and the insulating film 16. The shutter 28 has in its core a semiconductor layer 56 made of, for example, amorphous silicon. The first conducting film 54 is laminated on the semiconductor layer 56, such that the insulating film 16 covers the first conducting film 54. The first conducting film 54 is made of, for example, silicon-aluminum alloy, and the insulating film 16 is made of silicon nitride.

The first conducting film 54 and insulating film 16 which constitute part of the shutter 28 also constitute part of the driver 52. That is, the driver 52 contains a laminate structure of the first conducting film 54 and insulating film 16. Further, the semiconductor layer 56, which constitutes part of the shutter 28, also constitutes part of the driver 52. For example, the second spring 50, which is part of the driver 52, has in its core the semiconductor layer 56, and the first conducting film 54 is laminated on the semiconductor layer 56 such that the insulating film 16 covers the first conducting film 54.

A plurality of base layers 58 and 60 made of an insulator are laminated on the first substrate 10, and on top of them, the first opaque film 18 is formed. The first opaque film 18 is a conducting film formed by sandwiching an aluminum film with titanium films on the top and bottom. The conducting layer 14 made of ITO (indium tin oxide) or the like is formed on the first opaque film 18. The conducting layer 14 and first opaque film 18, which are both made of conductors, are electrically connected to each other, and at least one or them is arranged below the shutter 28.

On the first substrate 10 (specifically, on the conducting layer 14), a protruding part 62 is provided. The protruding part 62 has in its core a resin layer 64 made of a resin such as photoresist. On the resin layer 64, the semiconductor layer 56 which constitutes part of the shutter 28 is laminated. The first conducting film 54 and insulating film 16 which constitute part of the shutter 28 also constitute part of the protruding part 62. That is, the protruding part 62 contains a laminate structure of the first conducting film 54 and insulating film 16, and the insulating film 16 covers the first conducting film 54.

The first conducting film 54 which constitutes part of the protruding part 62 is electrically connected to the conducting layer 14 via the semiconductor layer 56 which constitutes part of the protruding part 62. In short, the first conducting film 54 is electrically connected to the first opaque film 18 and the conducting layer 14 arranged below the shutter 28.

The protruding part 62 has a plurality of side faces 66 which rise from the first substrate 10 so as to circumscribe a prescribed space. The outermost layer of the side faces 66 of the protruding part 62 is made of the insulating film 16 which covers the first conducting film 54. In the insulating film 16, the portion that constitutes the outermost layer of the side faces 66 is thinner than the portion that extends parallel to the surface of the first substrate 10. The insulating film 16 which forms the outermost layer of the side faces 66 has an aperture 68 which exposes part of the first conducting layer 54.

Conducting particles 70 are interposed between the first substrate 10 and the second substrate 12. The conducting particles 70 are obtained by forming a conducting layer such as metal on the surface of a core such as resin, and the core is an elastic body. The conducting particles 70 are arranged in the prescribed space circumscribed by the plurality of side faces 66. The conducting particles 70 elastically deform by being pressed by the plurality of side faces 66. The conducting particles 70, on the side nearest the first substrate 10, contact the first conducting film 54 exposed from the aperture 68 in the plurality of side faces 66, and contact the second conducting film 22 on the side nearest the second substrate 12. In short, the first conducting film 54 and the second conducting film 22 are at the same potential. The first opaque film 18 and the conducting layer 14 to which the first conducting film 54 is connected are arranged below the shutter 28. The second conducting film 22 is arranged above the shutter 28.

According to this embodiment, the first conducting film 54 formed on the first substrate 10 on which the shutter 28 is provided and the second conducting film 22 formed on the second substrate 12 that opposes it can be made electrically continuous by the conducting particles 70. As a result, the shutter 28 and the second substrate 12 can be prevented from sticking together due to electrostatic force because they are both at the same potential. The first conducting film 54 contacted by the conducting particles 70 is part of the laminate structure that constitutes the protruding part 62 which rises from the first substrate 10. On the side faces 66 of the protruding part 62, the direction of stacking of the insulating film 16 and the first conducting film 54 is a direction that intersects the direction in which the first substrate 10 and second substrate 12 oppose. Therefore, when the first substrate 10 and second substrate 12 are made to oppose each other, due to the conducting particles 70 moving in the direction in which the two oppose each other, it becomes easy to form the aperture 68 by peeling away part of the insulating film 16. Thus, the conducting particles 70 and the first conducting film 54 can connect electrically via the aperture 68 in the insulating film 16.

In this embodiment, the first substrate 10 and second substrate 12 are affixed with a gap in between by a seal member 72. As shown in FIG. 1, the seal member 72 is provided in a region that encloses the image display region 36, except for part of it. At the position where the seal member 72 is not provided, an encapsulation member 74 is provided. A space is encapsulated by the first substrate 10 and second substrate 12 and the seal member 72 and encapsulation member 74.

The conducting particles 70 are mixed into the seal member 72. Therefore, the protruding part 62 is formed in at least part of the region that encloses the image display region 36.

The space between the first substrate 10 and the second substrate 12 (the space encapsulated by the seal member 72 and encapsulation member 74) is filled with oil 76 (for example, silicone oil). The shutter 28 and driver 52 are arranged in the oil 76. Since the dielectric constant of the oil 76 is low, the drive voltage of the shutter 28 can be reduced. If the first substrate 10 and second substrate 12 are made of glass, reflection of light at the interface between the first substrate 10 and second substrate 12 can be reduced by loading the oil 76 having a refractive index close to that of glass.

Next, a method for producing a display device pertaining to an embodiment of the present invention will be described. In this embodiment, the shutter 28, driver 52 for driving the shutter 28 and protruding part 62 are provided on the first substrate 10 so as to contain a laminate structure of the first conducting film 54 and insulating film 16. The outermost layer of the respective plurality of side faces 66 is made of the insulating film 16 that covers the first conducting film 54. The insulating film 16 may be formed by deposition, and in that case, the portion that constitutes the outermost layer of the side faces 66 is thinner than the portion that extends parallel to the surface of the first substrate 10. Further, the second conducting film 22 is provided on the second substrate 12.

The side of the first substrate 10 on which the first conducting film 54 and insulating filml6 are provided and the side of the second substrate 12 on which the second conducting film 22 is provided are made to oppose each other. Also, the first substrate 10 and second substrate 12 are affixed by the seal member 72. If the seal member 72 is formed of resin, resin into which the conducting particles 70 have been mixed is used. The first substrate 10 and second substrate 12 are stuck together by the seal member 72, oil 76 is loaded from a slit in the seal member 72, and this is encapsulated by the encapsulation member 74.

Because the seal member 72 contains conducting particles 70, the conducting particles 70 become interposed between the first substrate 10 and second substrate 12 when the first substrate 10 and second substrate 12 are stuck together. The conducting particles 70 are pressed into the space circumscribed by the plurality of side faces 66 of the protruding part 62 by means of opposing forces being applied to the first substrate 10 and second substrate 12. At this time, the conducting particles 70 chip away the insulating film 16, which is the outermost layer of the side face 66, and form the aperture 68 that exposes part of the first conducting film 54. Since the prescribed space circumscribed by the plurality of side faces 66 is smaller than the conducting particles 70, the conducting particles 70 elastically deform and attach to the first conducting film 54. In this manner, the conducting particles 70, on the side nearest the first substrate 10, are put in contact with the first conducting film 54 which is exposed from the aperture 68 on the plurality of side faces 66, and on the side nearest the second substrate 12, are put in contact with the second conducting film 22.

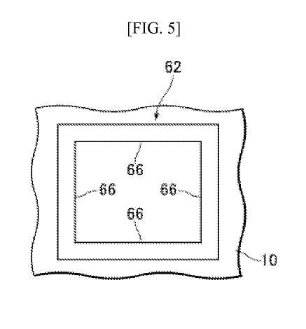

FIG. 5 is a plan view of the protruding part 62. The protruding part 62 is provided continuously so as to enclose the prescribed space. Therefore, the plurality of side faces 66 are formed integrally and continuously. In this example, the cross-sectional shape of the space enclosed by the protruding part 62 is rectangular, and the cross-sectional shape of the outside of the protruding part 62 is also rectangular.

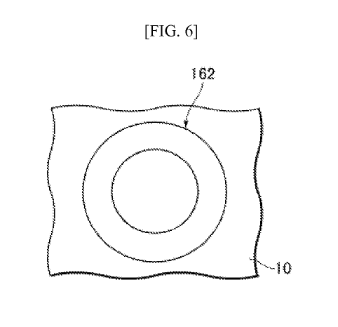

FIG. 6 is a plan view illustrating a first modification example of a protruding part 162. In this example, the cross-sectional shape of the space enclosed in the protruding part 162 is circular, and the cross-sectional shape of the outside of the protruding part 162 is also circular.

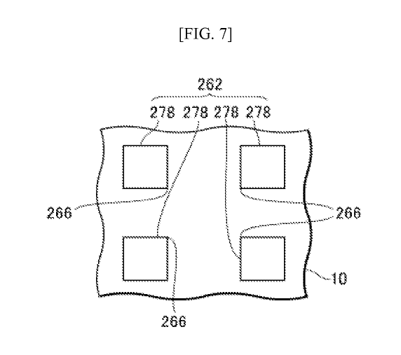

FIG. 7 is a plan view illustrating a second modification example of a protruding part 262. In this example, the protruding part 262 is split with a gap in between adjacent parts at positions that enclose a prescribed space. In short, the protruding part 262 is made of at least two (four in FIG. 7) opposing split portions 278. The side faces 266 of the protruding part 262 are side faces (for example, the corners) of the split portions 278. The plurality of side faces 266 each have an exterior corner shape. The cross-sectional shape of the split portions 278 is rectangular.

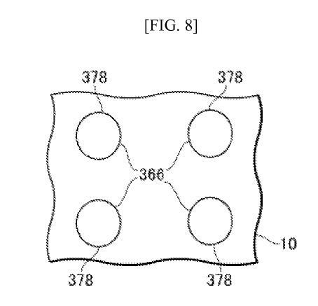

FIG. 8 is a plan view illustrating a third modification example of a protruding part. In this example, what differs from the example shown in FIG. 7 is the fact that the cross-sectional shape of the split portions 378 is circular. The plurality of side faces 366 are each a cylindrical face formed around an axis perpendicular to the first substrate 10.

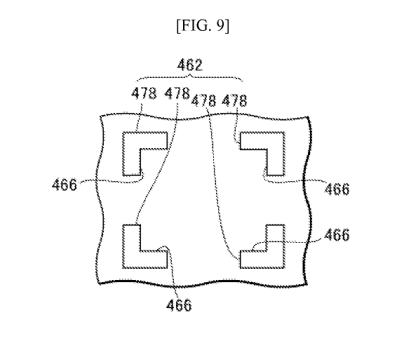

FIG. 9 is a plan view illustrating a fourth modification example of a protruding part 462. In this example, what differs from the example shown in FIG. 7 is the fact that the cross-sectional shape of the split portions 478 is an L shape. The interior shape of the L shape traced by the split portions 478 faces the space surrounded by the entire protruding part 462. The plurality of side faces 466 each have an interior corner shape.

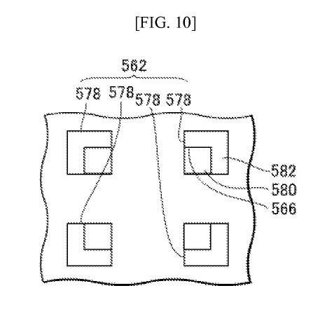

FIG. 10 is a plan view illustrating a fifth modification example of a protruding part 562. In this example, at least two opposing split potions 578 that constitute the protruding part 562 are each formed in a stair-like pattern. Specifically, the split portions 578 have a base 580 and a wall 582 which rises from the base 580. The side faces 566 of the protruding part 562 are the side faces of the walls 582. The plurality of side faces 566 each have an interior corner shape.

The present invention is not limited to the above-described embodiments and may be modified in various ways. Further, the features described in the embodiments may be replaced with features that have substantially the same features and same effects, or features that achieve the same objectives.

### DESCRIPTION OF REFERENCE NUMERALS

10 First substrate

12 Second substrate

14 Conducting layer

16 Insulating film

18 First opaque film

20 First fixed aperture

22 Second conducting film

24 Second opaque film

26 Second fixed aperture

28 Shutter

30 Drive aperture

32 Depression

34 Backlight

36 Image display region

38 First spring

40 First anchor

42 First part

44 Second part

46 Third part

48 Second anchor

50 Second spring

52 Driver

54 First conducting film

56 Semiconductor layer

58 Base layer

60 Base layer

62 Protruding part

64 Resin layer

66 Side face

68 Aperture

70 Conducting particles

72 Seal member

74 Encapsulation member

76 Oil

162 Protruding part

262 Protruding part

266 Side face

278 Split portion

366 Side face

378 Split portion

462 Protruding part

466 Side face

478 Split portion

562 Protruding part

566 Side face

578 Split portion

580 Base

582 Wall

What is claimed is:

1. A display device comprising
a first substrate,
a second substrate arranged so as to oppose the first substrate,
a first conducting film provided on the side of the first substrate nearest the second substrate,
an insulating film provided on the side of the first substrate nearest the second substrate so as to cover the first conducting film,
a second conducting film provided on the side of the second substrate nearest the first substrate, and
conducting particles interposed between the first substrate and second substrate, wherein, on the first substrate, a shutter which controls the passing or blocking of light, a driver for driving the shutter, and a protruding part having a plurality of side faces rising from the first substrate so as to circumscribe a prescribed space are respectively provided so as to contain a laminate structure of the first conducting film and the insulating film, and
the outermost layer of the respective plurality of side faces is made of the insulating film that covers the first conducting film, and has an aperture which exposes part of the first conducting film, and
the conducting particles are arranged in the prescribed space circumscribed by the plurality of side faces, and on the side nearest the first substrate, they contact the first conducting film exposed through the aperture in the plurality of side faces, and on the side nearest the second substrate, they contact the second conducting film.

2. The display device according to claim 1, wherein
the insulating film further contains a portion which extends parallel to the surface of the first substrate, and the portion that constitutes the outermost layer of the plurality of side faces is thinner than the portion that extends parallel to the surface of the first substrate.

3. The display device according to claim 1 or 2, wherein
the protruding part is provided continuously so as to enclose the prescribed space, and
the plurality of side faces are formed integrally and continuously.

4. The display device according to claim 1, wherein
the protruding part is formed in a fragmented manner so as to contain at least two opposing portions with a gap in between adjacent parts at positions that enclose the prescribed space, and
the plurality of side faces are each side faces of at least two opposing portions.

5. The display device according to claim 4, wherein
the at least two opposing portions are each formed in a stair-like pattern, and have a base and walls that rise from the base, and
the plurality of side faces are side faces of the walls of the at least two opposing portions.

6. The display device according to claim 4 or 5, wherein
the plurality of side faces each are a cylindrical face formed around an axis perpendicular to the first substrate.

7. The display device according to claim 4 or 5, wherein
the plurality of side faces each have an exterior corner shape.

8. The display device according to claim 4 or 5, wherein
the plurality of side faces each have an interior corner shape.

9. The display device according to any one of claims 1 through 8, wherein
the conducting particles are elastically deformed when being pressed by the plurality of side faces.

10. A method for producing a display device comprising
providing, on the first substrate, a shutter which controls the passing or blocking of light, a driver for driving the shutter, and a protruding part having a plurality of side faces rising from the first substrate so as to circumscribe a prescribed space are respectively provided so as to contain a laminate structure of the first conducting film and the insulating film,
providing a second conducting film on a second substrate, and
making the side of the first substrate on which the first conducting film and insulating film are provided and the side of the second substrate on which the second conducting film is provided oppose each other, and interposing conducting particles between the first substrate and second substrate, wherein
the outermost layer of each of the plurality of side faces is made of the insulating film that covers the first conducting film,
the prescribed space circumscribed by the plurality of side faces is smaller than the conducting particles, and
in interposing the conducting particles, by pressing the conducting particles in the prescribed region circumscribed by the plurality of side faces, the insulating film is chipped away and an aperture which exposes part of the first conducting film is formed in the insulating film, and
the conducting particles, on the side nearest the first substrate, are put in contact with the first conducting film exposed from the aperture in the plurality of side faces, and on the side nearest the second substrate, are put in contact with the second conducting film.
